(19) United States
(12) Patent Application Publication
(10) Pub. No.: US 2019/0244674 A1
(43) Pub. Date: Aug. 8, 2019

(54) MEMORY SYSTEM AND METHOD OF OPERATING THE SAME

(71) Applicant: SK hynix Inc., Gyeonggi-do (KR)

(72) Inventors: Hee Youl LEE, Gyeonggi-do (KR); Kyoung Cheol KWON, Gyeonggi-do (KR)

(21) Appl. No.: 16/114,770

(22) Filed: Aug. 28, 2018

(30) Foreign Application Priority Data
Feb. 6, 2018 (KR) 10-2018-0014695

(51) Int. Cl. G11C 16/34; G11C 16/10; G11C 16/08; G11C 16/26

(52) U.S. Cl. CPC G11C 16/3459; G11C 16/10; G11C 16/0483; G11C 16/26; G11C 16/08

(57) ABSTRACT

Provided herein may be a memory system and a method of operating the same. The memory system may include a memory device comprising a memory block composed of a plurality of strings, and a memory controller configured to control the memory device to perform a program operation on the memory block in response to a write request received from a host, wherein the memory device programs the plurality of strings by sequentially selecting the strings during the program operation.

### CROSS-REFERENCE TO RELATED APPLICATION

The present application claims priority under 35 U.S.C. § 119(a) to Korean patent application number 10-2018-0014695, filed on Feb. 6, 2018, which is incorporated herein by reference in its entirety.

### BACKGROUND

### 1. Field of Invention

Various embodiments of the present disclosure generally relate to a memory system and a method of operating the memory system. Particularly, the embodiments relate to a memory system capable of improving threshold voltage distributions of memory cells during a program operation, and a method of operating the memory system.

### 2. Description of Related Art

The computer environment paradigm has been shifting to ubiquitous computing, which enables computing systems to be used anytime and anywhere. As a result, the use of portable electronic devices such as mobile phones, digital cameras, and laptop computers has rapidly increased. In general, such portable electronic devices use a memory system which employs a memory device, in other words, use a data storage device. The data storage device may be used as a main memory device or an auxiliary memory device for portable electronic devices.

Since there is no mechanical driving part, a data storage device using a memory device provides advantages such as excellent stability and durability, high information access speed, and low power consumption. Data storage devices, as an example of the memory system having such advantages, include a universal serial bus (USB) memory device, memory cards having various interfaces, and a solid state drive (SSD).

### SUMMARY

Various embodiments of the present disclosure are directed to a memory system capable of improving threshold voltage distributions of memory cells, and a method of operating the memory system.

An embodiment of the present disclosure may provide for a memory system. The memory system may include a memory device including a memory block composed of a plurality of strings, and a memory controller configured to control the memory device to perform a program operation on the memory block in response to a write request received from a host, wherein the memory device programs the plurality of strings by sequentially selecting the strings during the program operation.

An embodiment of the present disclosure may provide for a memory system. The memory system may include a memory device including a plurality of pages each having a plurality of sub-pages; and a controller configured to control the memory device to: program data into memory cells coupled to a first sub-page of a first page among the plurality of pages; program data into memory cells coupled to the first sub-page of a subsequent page and then program data into memory cells coupled to a sequence of remaining sub-pages of a previous page among the pages; and program data into memory cells coupled to the sequence of remaining sub-pages of a last page among the pages, wherein the memory device includes a plurality of strings each coupled to the first sub-page and the sequence of remaining sub-pages, and wherein the memory device sequentially programs the data by sequentially selecting the strings.

An embodiment of the present disclosure may provide for a method of operating a memory system. The method may include performing a first program operation by selecting a first page from among a plurality of pages of a memory block, performing the first program operation by selecting a second page from among the plurality of pages, performing a second program operation by selecting the first page, performing the first program operation by selecting a third page from among the plurality of pages, and performing the second program operation by selecting the second page, wherein the first program operation is configured to sequentially select and program memory cells included in the selected page.

An embodiment of the present disclosure may provide for a method of operating a memory system. The method may include performing a first program operation by selecting a first page from among a plurality of pages of a memory block, performing the first program operation by selecting a second page from among the plurality of pages, successively performing a second program operation and a third program operation by selecting the first page, performing the first program operation by selecting a third page from among the plurality of pages, successively performing the second program operation and the third program operation by selecting the second page, and performing the first program operation by selecting a fourth page from among the plurality of pages, wherein the first program operation is configured to sequentially select and program memory cells included in the selected page.

### BRIEF DESCRIPTION OF THE DRAWINGS

FIG. 1 is a diagram illustrating a memory system according to an embodiment of the present disclosure.

FIG. 2 is a diagram illustrating a memory device of FIG. 1

FIG. 3 is a diagram illustrating a memory block of FIG. 2.

FIG. 4 is a diagram illustrating an example of a memory block having a three-dimensional (3D) structure.

FIG. 5 is a diagram illustrating an example of a memory block having a 3D structure.

FIG. 6 is a flowchart illustrating a program operation of a memory system according to an embodiment of the present disclosure.

FIG. 7 is a diagram illustrating the sequence of program operations according to an embodiment of the present disclosure.

FIG. 8 is a diagram illustrating retention characteristics of a memory cell after a first program operation.

FIG. 9 is a threshold voltage distribution diagram explaining a program operation of a memory system according to an embodiment of the present disclosure.

FIG. 10 is a flowchart illustrating a program operation of a memory system according to an embodiment of the present disclosure.

FIG. 11 is a diagram illustrating the sequence of program operations according to an embodiment of the present disclosure.

FIG. 12 is a diagram illustrating an embodiment of a memory system including the memory device of FIG. 2.

FIG. 13 is a diagram illustrating an embodiment of a memory system including the memory device of FIG. 2.

FIG. 14 is a diagram illustrating an embodiment of a memory system including the memory device of FIG. 2.

FIG. 15 is a diagram illustrating an embodiment of a memory system including the memory device of FIG. 2.

### DETAILED DESCRIPTION

Advantages and features of the present disclosure, and methods for achieving the advantages and features will be described in more detail with reference to embodiments described later along with the accompanying drawings. The present disclosure is not limited to the following embodiments but may be embodied in other forms. Rather, these embodiments are provided so that the present disclosure will be thorough and complete, and will fully convey the technical spirit of the disclosure to those skilled in the art. Throughout the disclosure, like reference numerals refer to like parts throughout the various figures and embodiments of the present invention. It is noted that reference to “an embodiment” does not necessarily mean only one embodiment, and different references to “an embodiment” are not necessarily to the same embodiment(s).

The drawings are not necessarily to scale and, in some instances, proportions may have been exaggerated in order to clearly illustrate features of the embodiments.

The terminology used herein is for the purpose of describing particular embodiments only and is not intended to be limiting of the present invention.

As used herein, singular forms may include the plural forms as well and vice versa, unless the context clearly indicates otherwise.

It is also noted that in this specification, “connected/coupled” refers to one component not only directly coupling another component but also indirectly coupling another component through an intermediate component. In the specification, when an element is referred to as “comprising” or “including” a component, it does not preclude another component but may further include other components unless the context clearly indicates otherwise. As used herein, the term “and/or” includes any and all combinations of one or more of the associated listed items.

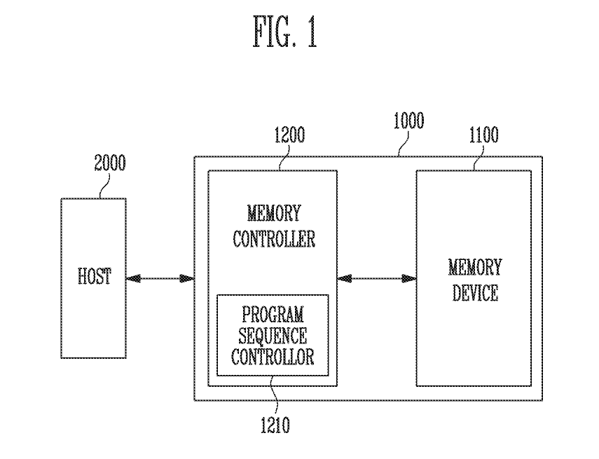

FIG. 1 is a diagram illustrating a memory system according to an embodiment of the present disclosure.

Referring to FIG. 1, a memory system 1000 may include a memory device 1100 for storing data and a memory controller 1200 for controlling the memory device 1100 under the control of a host 2000.

The host 2000 may communicate with the memory system 1000 using an interface protocol such as a peripheral component interconnect-express (PCI-E), an advanced technology attachment (ATA), a serial ATA (SATA), a parallel ATA (PATH) or a serial attached SCSI (SAS). In addition, the interface protocol provided for the purpose of data communication between the host 2000 and the memory system 1000 is not limited to the above examples and may be an interface protocol such as a Universal Serial Bus (USB), a Multi-Media Card (MMC), an Enhanced Small Disk Interface (ESDI), or Integrated Drive Electronics (IDE).

The memory controller 1200 may control overall operations of the memory system 1000 and may control data exchange between the host 2000 and the memory device 1100. For example, the memory controller 1200 may program or read data by controlling the memory device 1100 in response to a request from the host 2000. Further, the memory controller 1200 may store information of main memory blocks and memory blocks included in the memory device 1100, and may select the memory device 1100 so that a program operation is performed on a main memory block or a memory block depending on the amount of data that is loaded for the program operation. In an embodiment, non-limiting examples of the memory device 1110 may include a double data rate synchronous dynamic random access memory (DDR SDRAM), a low power double data rate fourth generation (LPDDR4) SDRAM, a graphics double data rate SDRAM (DDDR SDRAM), a low power DDR (LPDDR) SDRAM, a Rambus dynamic random access memory (RDRAM), or a flash memory.

The memory controller 1200 may include a program sequence controller 1210. The program sequence controller 1210 may set a program sequence for a plurality of strings included in a memory block, which is selected from among a plurality of memory blocks included in the memory device 1100 and on which a program operation is to be performed when a write request is received from the host 2000. For example, the program sequence controller 1210 may set the program sequence so that the plurality of strings included in the selected memory block are sequentially programmed. For example, the program sequence controller 1210 may set the program sequence so that the plurality of strings included in the selected memory block sequentially perform a first program operation, and thereafter sequentially perform a second program operation. For example, the program sequence controller 1210 may set the program sequence so that the plurality of strings included in the selected memory block sequentially perform the first program operation, and then sequentially perform the second program operation with a predetermined period of wait time between the first and second program operations. During the predetermined period of wait time, charges in memory cells that the first program operation is performed to may be rearranged.

Although FIG. 1 shows the program sequence controller 1210 illustrated and described as being included in the memory controller 1200, the present disclosure is not limited to such an embodiment. That is, the program sequence controller 1210 may be configured to be included as an element of the memory device 1100.

The memory device 1100 may perform a program operation, a read operation, or an erase operation under the control of the memory controller 1200

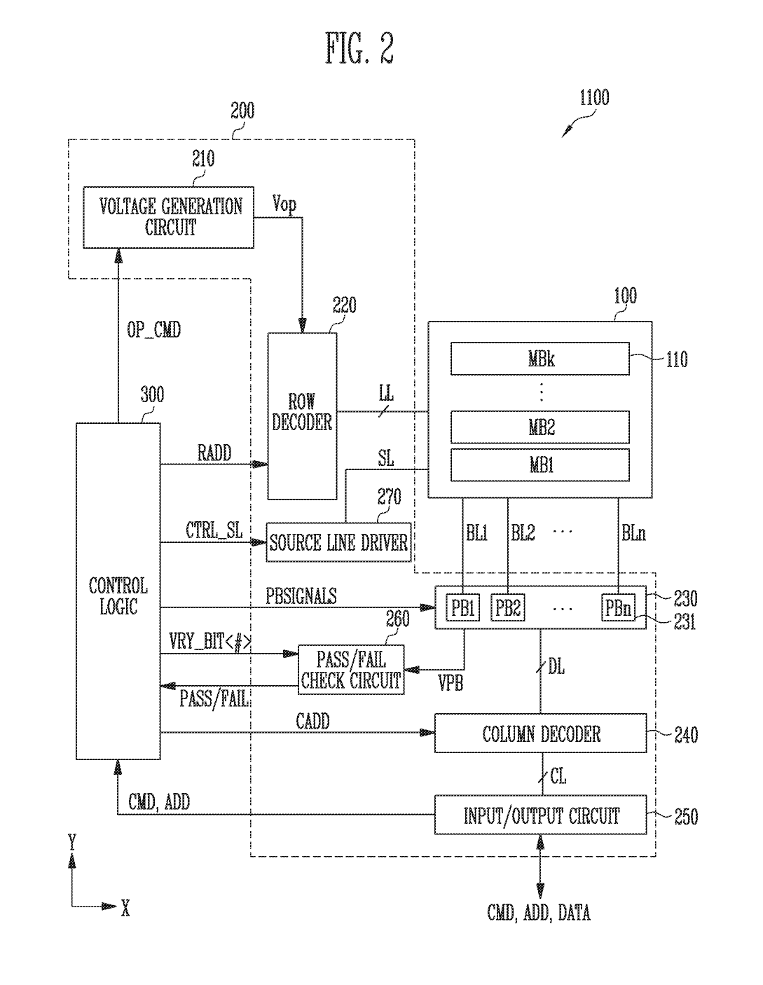

FIG. 2 is a diagram illustrating the memory device of FIG. 1.

Referring to FIG. 2, the memory device 1100 may include a memory cell array 100 in which data is stored. The memory device 1100 may also include peripheral circuits 200, which perform a program operation for storing data in the memory cell array 100, a read operation for outputting stored data, and an erase operation for erasing stored data. The memory device 1100 may include a control logic 300, which controls the peripheral circuits 200 under the control of a memory controller (e.g., 1200 of FIG. 1).

The memory cell array 100 may include a plurality of memory blocks MB1 to MBk 110 (where k is a positive integer). Local lines LL and bit lines BL1 to BLn (where n is a positive integer) may be coupled to each of the memory blocks MB1 to MBk 110. For example, the local lines LL may include a first select line, a second select line, and a plurality of word lines arranged between the first and second select lines. Further, the local lines LL may include dummy lines arranged between the first select line and the word lines and between the second select line and the word lines. Here, the first select line may be a source select line, and the second select line may be a drain select line. For example, the local lines LL may include word lines, drain and source select lines, and source lines. For example, the local lines LL may further include dummy lines. For example, the local lines LL may further include pipelines. The local lines LL may be coupled to the memory blocks MB1 to MBk 110, respectively, and the bit lines BL1 to BLn may be coupled in common to the memory blocks MB1 to MBk 110. The memory blocks MB1 to MBk 110 may be implemented as a two-dimensional (2D) or a three-dimensional (3D) structure. For example, the memory cells in the memory blocks 110 having a 2D structure may be arranged horizontally on a substrate. For example, memory cells in the memory blocks 110 having a 3D structure may be stacked vertically on the substrate.

The peripheral circuits 200 may perform a program, read, or erase operation on a selected memory block 110 under the control of the control logic 300. For example, the peripheral circuits 200 may perform first and second program operations or first to third program operations under the control of the control logic 300.

Depending on an embodiment, the peripheral circuits 200 may perform a program operation on the selected memory block 110 using a multi-level cell (MLC) program scheme that is capable of programming two bits of data or a triple-level cell (TLC) program scheme that is capable of programming three bits of data. The MLC program scheme may include a first program operation of programming Least Significant Bit (LSB) data and a second program operation of programming Most Significant Bit (MSB) data. The TLC program scheme may include a first program operation of programming LSB data, a second program operation of programming Central Significant Bit (CSB) data, and a third program operation of programming MSB data.

In an embodiment, the peripheral circuits 200 may perform a program operation using a re-program scheme, which includes a first program operation and a second program operation, when storing at least two bits of data in memory cells. Each memory cell may be primarily programmed to a first target level by performing a first program operation, and may be secondarily programmed to a second target level by performing a second program operation. The first target level and the second target level may be the same threshold voltage level, or alternatively the first target level may be a threshold voltage level lower than the second target level. The above-described reprogram scheme may include first to y-th (where y is an integer of 2 or more) program operations, and target levels of respective program operations may be the same level, or alternatively, the target level of the first program operation may be lower than those of other program operations.

The peripheral circuits 200 may perform the first program operation so that the plurality of strings included in the selected memory block 110 are sequentially programmed, perform the second program operation so that the plurality of strings are sequentially programmed, and perform the third program operation so that the plurality of strings are sequentially programmed.

The peripheral circuits 200 may include a voltage generation circuit 210, a row decoder 220, a page buffer group 230, a column decoder 240, an input/output circuit 250, a pass/fail check circuit 260, and a source line driver 270.

The voltage generation circuit 210 may generate various operation voltages Vop used for program, read, and erase operations in response to an operation signal OP_CMD. Further, the voltage generation circuit 210 may selectively discharge the local lines LL in response to the operation signal OP_CMD. For example, the voltage generation circuit 210 may generate a program voltage, a verify voltage, pass voltages, a read voltage, a source line voltage, etc. under the control of the control logic 300.

The row decoder 220 may transfer the operation voltages Vop to the local lines LL coupled to a selected memory block 110 in response to a row address RADD.

The page buffer group 230 may include a plurality of page buffers PB1 to PBn 231 coupled to the bit lines BL1 to BLn. The page buffers PB1 to PBn 231 may be operated in response to page buffer control signals PBSIGNALS. For example, during a program operation, the page buffers PB1 to PBn 231 may temporarily store data received through the column decoder 240, and may control the potential levels of corresponding bit lines BL1 to BLn based on the stored data. Further, during the program operation, the page buffers PB1 to PBn 231 may be sequentially activated, and may control the potential levels of corresponding bit lines based on the temporarily stored data in the activated state. The remaining page buffers, that is, deactivated page buffers, may apply a program prohibition voltage (e.g., supply voltage) to the corresponding bit lines. For example, during the program operation, the page buffer PB1 is activated to control the potential level of the bit line BL1 based on data stored in the page buffer PB1. After the program operation on the memory cell coupled to the bit line BL1 is completed, the page buffer PB2 is activated to control the potential level of the bit line BL2 based on data stored in the page buffer PB2. As in the case of the above-described operations, the page buffers PB1 to PBn 231 may be sequentially activated.

The column decoder 240 may transfer data between the input/output circuit 250 and the page buffer group 230 in response to a column address CADD. For example, the column decoder 240 may exchange data with the page buffers 231 through data lines DL or may exchange data with the input/output circuit 250 through column lines CL.

The input/output circuit 250 may transmit a command CMD and an address ADD, received from the memory controller (e.g., 1200 of FIG. 1), to the control logic 300, or may exchange data DATA with the column decoder 240.

The pass/fail check circuit 260 may generate a reference current in response to an enable bit VRY_BIT<#> and may output a pass signal PASS or a fail signal FAIL by comparing a sensing voltage VPB, received from the page buffer group 230, with a reference voltage, generated based on the reference current, during the read operation or the verify operation.

The source line driver 270 may be coupled to memory cells included in the memory cell array 100 through a source line SL, and may control the voltage of a source node. In an example, the source line driver 270 may electrically couple the source node of each memory cell to a ground node during a read or verify operation. Further, the source line driver 270 may apply a ground voltage to the source node of each memory cell during a program operation. The source line driver 270 may apply an erase voltage to the source node of each memory cell during an erase operation. The source line driver 270 may receive a source line control signal CTRL_SL from the control logic 300, and may control the voltage of the source node in response to the source line control signal CTRL_SL.

The control logic 300 may control the peripheral circuits 200 by outputting the operation signal OP_CMD, the row address RADD, the page buffer control signals PBSIGNALS, and the enable bit VRY_BIT<#> in response to the command CMD and the address ADD. Further, the control logic 300 may determine whether a verify operation has passed or failed in response to a pass or fail signal PASS or FAIL.

The memory device 1100 according to the embodiment of the present disclosure may sequentially select a plurality of strings included in a selected memory block and program the selected strings when a program operation is performed on a memory block selected from among the plurality of memory blocks MB1 to MBk 110. For example, during an MLC program operation, a first program operation may be performed such that the plurality of strings included in the selected memory block 110 are sequentially programmed, and a second program operation may be performed such that the plurality of strings are sequentially programmed. During a TLC program operation, a first program operation may be performed such that the plurality of strings included in the selected memory block 110 are sequentially programmed, a second program operation may be performed such that the plurality of strings are sequentially programmed, and a third program operation may be performed such that the plurality of strings are sequentially programmed.

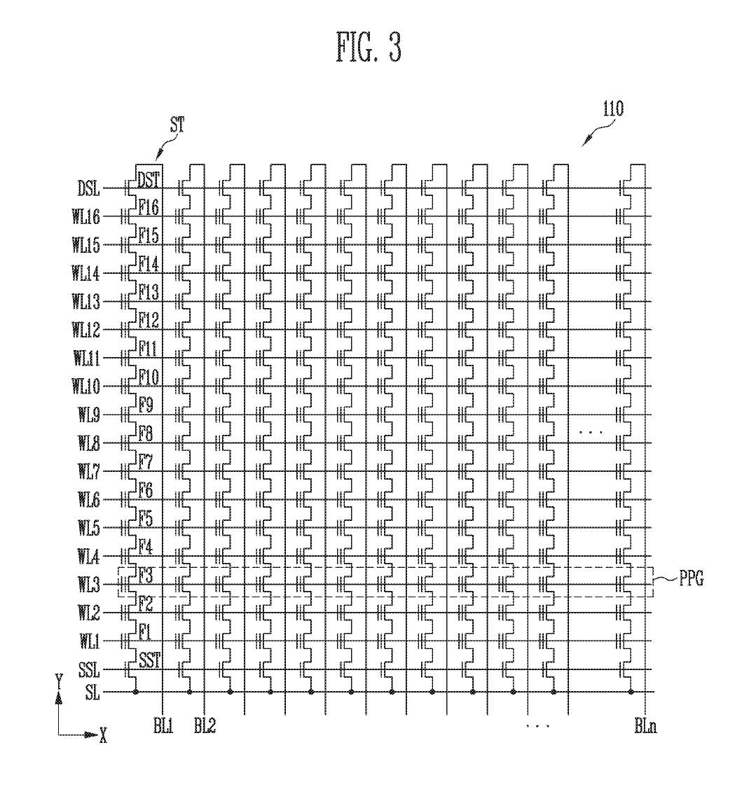

FIG. 3 is a diagram illustrating the memory block of FIG. 2.

Referring to FIG. 3, the memory block 110 may be configured such that a plurality of word lines, which are arranged in parallel, are coupled between a first select line and a second select line. Here, the first select line may be a source select line SSL and the second select line may be a drain select line DSL. In detail, the memory block 110 may include a plurality of strings ST coupled between bit lines BL1 to BLn and a source line SL. The bit lines BL1 to BLn may be respectively coupled to the strings ST, and the source line may be coupled in common to the strings ST. Since the strings ST may have the same configuration, a string ST coupled to the first bit line BL1 will be described in detail by way of example.

The string ST may include a source select transistor SST, a plurality of memory cells F1 to F16, and a drain select transistor DST, which are connected in series between the source line SL and the first bit line BL1. A single string ST may include one or more source select transistors SST and drain select transistors DST, and may include more memory cells than the memory cells F1 to F16 illustrated in the drawing.

A source of the source select transistor SST may be coupled to the source line SL and a drain of the drain select transistor DST may be coupled to the first bit line BL1. The memory cells F1 to F16 may be connected in series between the source select transistor SST and the drain select transistor DST. Gates of the source select transistors SST included in different strings ST may be coupled to a source select line SSL, gates of the drain select transistors DST may be coupled to a drain select line DSL, and gates of the memory cells Fl to F16 may be coupled to a plurality of word lines WL1 to WL16. A group of memory cells coupled to the same word line, among the memory cells included in different strings ST, may be referred to as a “physical page PPG.” Therefore, a number of physical pages PPG that are identical to the number of word lines WL1 to WL16 may be included in the memory block 110.

One memory cell may store one bit of data. This is typically referred to as a single-level cell (SLC). In this case, one physical page PPG may store data corresponding to one logical page LPG. The data corresponding to one logical page LPG may include a number of data bits identical to the number of cells included in one physical page PPG. Further, one memory cell may store two or more bits of data. This cell is typically referred to as a multi-level cell (MLC). Here, one physical page PPG may store data corresponding to two or more logical pages LPG.

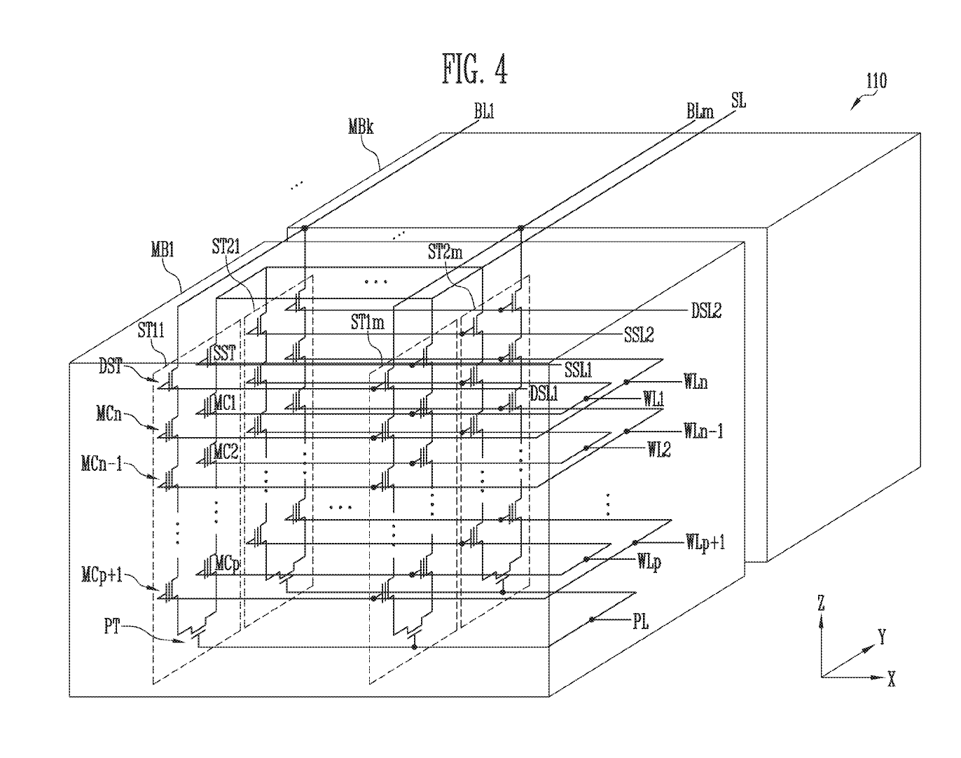

FIG. 4 is a diagram illustrating an example of a memory block having a three-dimensional (3D) structure.

Referring to FIG. 4, a memory cell array 100 may include a plurality of memory blocks MB1 to MBk 110. Each of the memory blocks 110 may include a plurality of strings ST11 to ST1m and ST21 to ST2m. In an embodiment, each of the strings ST11 to ST1m and ST21 to ST2m may be formed in a ‘U’ shape. In the first memory block MB1, m strings may be arranged in a row direction (e.g., X direction). Although, in FIG. 4, two strings are illustrated as being arranged in a column direction is (e.g., Y direction), this embodiment is merely an example, and three or more strings may be arranged in the column direction (e.g., Y direction) in other embodiments.

Each of the plurality of strings ST11 to ST1m and ST21 to ST2m may include at least one source select transistor SST, first to n-th memory cells MC1 to MCn, a pipe transistor PT, and at least one drain select transistor DST.

The source and drain select transistors SST and DST and the memory cells MC1 to MCn may have a similar structure. For example, each of the source and drain select transistors SST and DST and the memory cells MC1 to MCn may include a channel layer, a tunnel insulating layer, a charge trap layer, and a blocking insulating layer. For example, a pillar for providing the channel layer may be provided in each string. For example, a pillar for providing at least one of the channel layer, the tunnel insulating layer, the charge trap layer, and the blocking insulating layer may be provided in each string.

The source select transistor SST of each string may be coupled between a source line SL and memory cells MC1 to MCp.

In an embodiment, source select transistors of strings arranged in the same row may be coupled to a source select line extending in the row direction, and source select transistors of strings arranged in different rows may be coupled to different source select lines. In FIG. 4, the source select transistors of the strings ST11 to ST1m in a first row may be coupled to a first source select line SSL1. The source select transistors of the strings ST21 to ST2m in a second row may be coupled to a second source select line SSL2.

In other embodiments, the source select transistors of the strings ST11 to ST1m and ST21 to ST2m may be coupled in common to a single source select line.

The first to n-th memory cells MC1 to MCn in each string may be coupled between the source select transistor SST and the drain select transistor DST.

The first to n-th memory cells MC1 to MCn may be divided into first to p-th memory cells MC1 to MCp and p+1-th to n-th memory cells MCp+1 to MCn. The first to p-th memory cells MC1 to MCp may be sequentially arranged in a vertical direction (e.g., Z direction), and may be coupled in series between the source select transistor SST and the pipe transistor PT. The p+1-th to nth memory cells MCp+1 to MCn may be sequentially arranged in the vertical direction (e.g., Z direction), and may be coupled in series between the pipe transistor PT and the drain select transistor DST. The first to p-th memory cells MC1 to MCp and the p+1-th to n-th memory cells MCp+1 to MCn may be coupled to each other through the pipe transistor PT. Gates of the first to n-th memory cells MC1 to MCn of each string may be coupled to first to n-th word lines WL1 to WLn, respectively.

In an embodiment, at least one of the first to n-th memory cells MC1 to MCn may be used as a dummy memory cell. When the dummy memory cell is provided, the voltage or current of the corresponding string may be stably controlled. A gate of the pipe transistor PT of each string may be coupled to a pipeline PL.

The drain select transistor DST of each string may be coupled between the corresponding bit line and the memory cells MCp+1 to MCn. Strings arranged in the row direction may be coupled to the corresponding drain select line extending in the row direction. The drain select transistors of the strings ST11 to ST1m in the first row may be coupled to a drain select line DSL1. The drain select transistors of the strings ST21 to ST2m in the second row may be coupled to a second drain select line DSL2.

The strings arranged in the column direction may be coupled to bit lines extending in the column direction. In FIG. 4, the strings ST11 and ST21 in a first column may be coupled to a first bit line BL1, The strings ST1m and ST2m in an m-th column may be coupled to an m-th bit line BLm.

Among strings arranged in the row direction, memory cells coupled to the same word line may constitute one page. For example, memory cells coupled to the first word line WL1, among the strings ST11 to ST1m in the first row, may constitute one page. Among the strings ST21 to ST2m in the second row, memory cells coupled to the first word line WL1 may constitute one additional page. Strings arranged in the direction of a single row may be selected by selecting any one of the drain select lines DSLI and DSL2. One page may be selected from the selected strings by selecting any one of the word lines WL1 to WLn.

FIG. 5 is a diagram illustrating an example of a memory block having a 3D structure.

Referring to FIG. 5, a memory cell array 100 may include a plurality of memory blocks MB1 to MBk 110. Each of the memory blocks 110 may include a plurality of strings ST11′ to ST1m′ and ST21′ to ST2m′. Each of the strings ST11′ to ST1m′ and ST21′ to ST2m′ may extend along a vertical direction (e.g., z direction). In the memory block 110, m strings may be arranged in a row direction (e.g., X direction). Although, in FIG. 5, two strings are illustrated as being arranged in a column direction (e.g., Y direction), this embodiment is given for convenience of description, and three or more strings may be arranged in the column direction (e.g., Y direction) in other embodiments.

Each of the strings ST11′ to ST1m′ and ST21′ to ST2m′ may include at least one source select transistor SST, first to nth memory cells MC1 to MCn, and at least one drain select transistor DST.

The source select transistor SST of each string may be coupled between a source line SL and the memory cells MC1 to MCn. Source select transistors of strings arranged in the same row may be coupled to the same source select line. The source select transistors of the strings ST11′ to ST1m′ arranged in a first row may be coupled to a first source select line SSL1. The source select transistors of the strings ST21′ to ST2m′ arranged in a second row nr ay be coupled to a second source select line SSL2. In an embodiment, the source select transistors of the strings ST11′ to ST1m′ and ST21′ to ST2m′ may be coupled in common to a single source select line.

The first to n-th memory cells MC1 to MCn in each string may be coupled in series between the source select transistor SST and the drain select transistor DST. Gates of the first to n-th memory cells MC1 to MCn may be coupled to first to n-th word lines WL1 to WLn, respectively.

In an embodiment, at least one of the first to n-th memory cells MC1 to MCn may be used as a dummy memory cell. When the dummy memory cell is provided, the voltage or current of the corresponding string may be stably controlled. Thereby, the reliability of data stored in the memory block 110 may be improved.

The drain select transistor DST of each string may be coupled between the corresponding bit line and the memory cells MC1 to MCn. The drain select transistors DST of strings arranged in the row direction may be coupled to a drain select line extending along the row direction. The drain select transistors DST of the strings ST11′ to ST1m′ in the first row may be coupled to a first drain select line DSL1. The drain select transistors DST of the strings ST21′ to ST2m′ in the second row may be coupled to a second drain select line DSL2.

In summary, the memory block 110 of FIG. 5 may be substantially similar to the memory block 110 of FIG. 4. That is, the pipe transistor PT may be excluded from each string in the memory block 110 of FIG. 5.

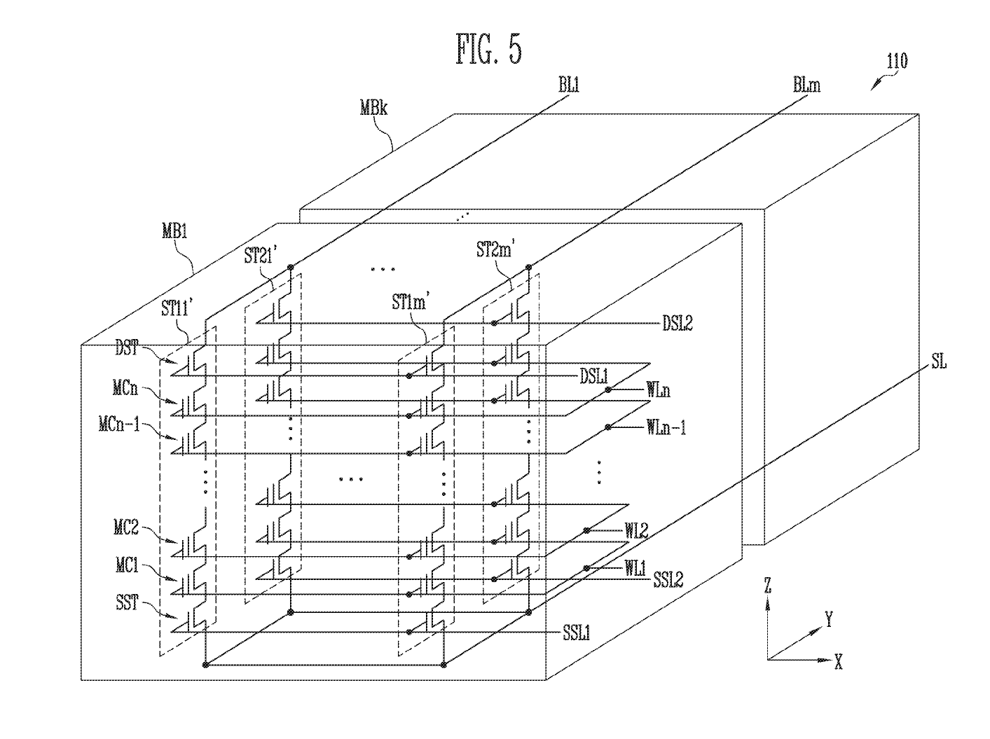

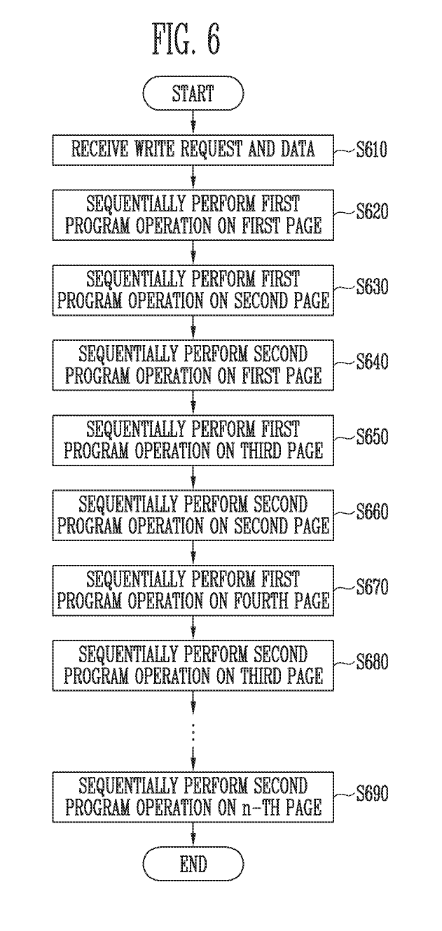

FIG. 6 is a flowchart illustrating a program operation of a memory system according to an embodiment of the present disclosure.

FIG. 7 is a diagram illustrating the sequence of program operations according to an embodiment of the present disclosure. FIG. 7 shows memory cells with numbers representing a program sequence.

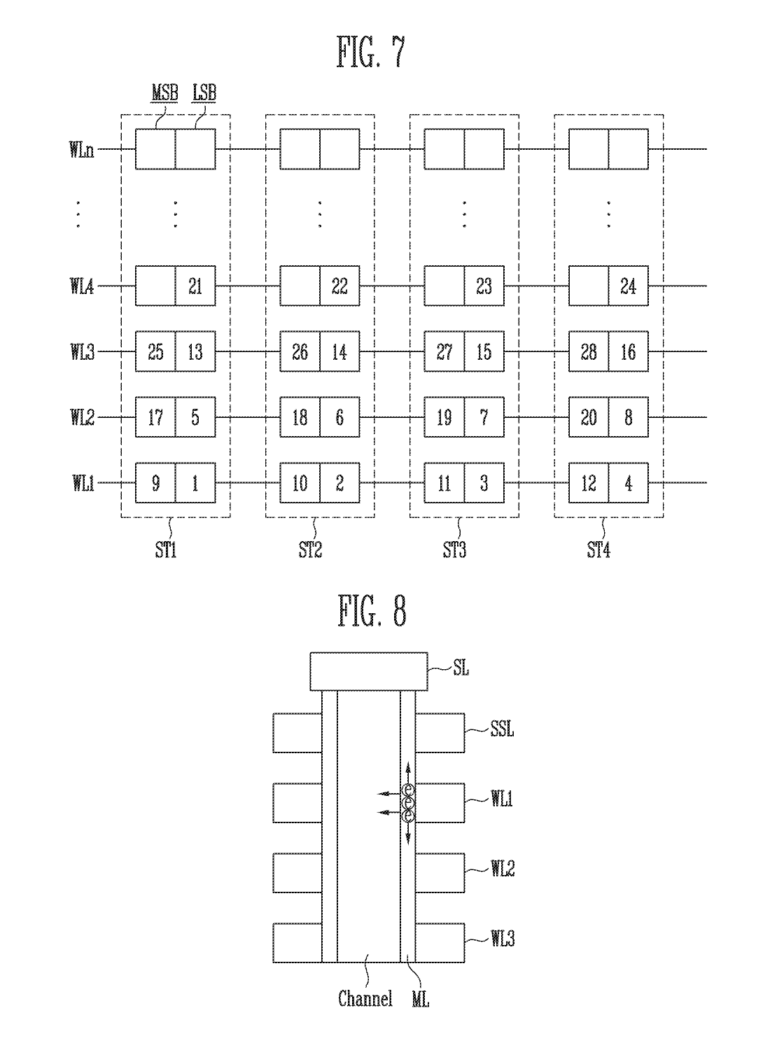

FIG. 8 is a diagram illustrating retention characteristics of a memory cell after a first program operation.

The program operation of the memory system according to the embodiment of the present disclosure will be described below with reference to FIGS. 1 to 8.

In an embodiment of the present disclosure, an operation of programming memory cells in an MLC scheme will be described by way of example. However, it is to be noted that the present invention is not limited to the MLC scheme.

When a write request and data are inputted from a host 2000 at step S610, the memory controller 1200 generates a command CMD for controlling the write operation of the memory device 1100 in response to the write request, translates an address received together with the write request into the address of the memory device 1100, and then generates a translated address ADD.

The program sequence controller 1210 of the memory controller 1200 sets a program sequence for a plurality of strings included in a memory block, which is selected from among a plurality of memory blocks included in the memory device 1100 and on which a program operation is to be performed, in response to the write request. For example, the program sequence controller 1210 may set the program sequence so that the plurality of strings included in the selected memory block are sequentially selected and programmed.

The memory controller 1200 transmits the command CMD, the data, and the address ADD to the memory device 1100.

The control logic 300 of the memory device 1100 outputs an operation signal OP_CMD, a row address RADD, and page buffer control signals PBSIGNALS in response to the command CMD and the address ADD, and then controls the peripheral circuits 200 so that the peripheral circuits 200 perform a first program operation on a first page composed of memory cells coupled to a word line WL1, from the selected memory block (e.g., MB1), wherein the memory cells are sequentially selected and programmed, at step S620.

Referring to FIG. 7, after LSB data is programmed to a memory cell included in a first string ST1, among memory cells coupled to the word line WL1 (program sequence 1), the LSB data is programmed to a memory cell included in a second string ST2, among the memory cells coupled to the word line WL1 (program sequence 2). Thereafter, after LSB data is programmed to a memory cell included in a third string ST3, among the memory cells coupled to the word line WL1 (program sequence 3), the LSB data is programmed to a memory cell included in a fourth string ST4, among the memory cells coupled to the word line WL1 (program sequence 4). As described above, the first program operation may be performed by sequentially selecting memory cells corresponding to the first page from among the plurality of strings included in the selected memory block and by programming LSB data to the selected memory cells.

Thereafter, the peripheral circuits 200 may perform the first program operation on a second page composed of memory cells coupled to a word line WL2, from the selected memory block, under the control of the control logic 300, and may be controlled such that the memory cells are sequentially selected and programmed, at step S630.

Referring to FIG. 7, after LSB data is programmed to a memory cell included in the first string ST1, among the memory cells coupled to the word line WL2 (program sequence 5), the LSB data is programmed to a memory cell included in the second string ST2, among the memory cells coupled to the word line WL2 (program sequence 6). Thereafter, after LSB data is programmed to a memory cell included in the third string ST3, among the memory cells coupled to the word line WL2 (program sequence 7), the LSB data is programmed to a memory cell included in the fourth string ST4, among the memory cells coupled to the word line WL2 (program sequence 8). As described above, the first program operation may be performed by sequentially selecting memory cells corresponding to the second page, among the plurality of strings included in the selected memory block, and by programming LSB data to the selected memory cells.

Thereafter, the peripheral circuits 200 may perform a second program operation on the first page of the selected memory block under the control of the control logic 300, and may be controlled such that memory cells are sequentially selected and programmed, at step S640.

Referring to FIG. 7, after MSB data is programmed to the memory cell included in the first string ST1, among memory cells coupled to the word line WL1 (program sequence 9), the MSB data is programmed to the memory cell included in the second string ST2, among the memory cells coupled to the word line WL1 (program sequence 10). Thereafter, after MSB data is programmed to the memory cell included in the third string ST3, among the memory cells coupled to the word line WL1 (program sequence 11), the MSB data is programmed to the memory cell included in the fourth string ST4, among the memory cells coupled to the word line WL1 (program sequence 12). As described above, the second program operation may be performed by sequentially selecting memory cells corresponding to the first page from among the plurality of strings included in the selected memory block and by programming MSB data to the selected memory cells.

Thereafter, the peripheral circuits 200 may perform the first program operation on a third page composed of memory cells coupled to a word line WL3, from the selected memory block, under the control of the control logic 300, and may be controlled such that the memory cells are sequentially selected and programmed, at step S650.

Referring to FIG. 7, after LSB data is programmed to a memory cell included in the first string ST1, among the memory cells coupled to the word line WL3 (program sequence 13), the LSB data is programmed to a memory cell included in the second string ST2, among the memory cells coupled to the word line WL3 (program sequence 14). Thereafter, after LSB data is programmed to a memory cell included in the third string ST3, among the memory cells coupled to the word line WL3 (program sequence 15), the LSB data is programmed to a memory cell included in the fourth string ST4, among the memory cells coupled to the word line WL3 (program sequence 16). As described above, the first program operation may be performed by sequentially selecting memory cells corresponding to the third page, among the plurality of strings included in the selected memory block, and by programming LSB data to the selected memory cells.

Thereafter, the peripheral circuits 200 may perform a second program operation on the second page of the selected memory block under the control of the control logic 300, and may be controlled such that memory cells are sequentially selected and programmed, at step S660.

Referring to FIG. 7, after MSB data is programmed to the memory cell included in the first string ST1, among the memory cells coupled to the word line WL2 (program sequence 17), the MSB data is programmed to the memory cell included in the second string ST2, among the memory cells coupled to the word line WL2 (program sequence 18). Thereafter, after MSB data is programmed to the memory cell included in the third string ST3, among the memory cells coupled to the word line WL2 (program sequence 19), the MSB data is programmed to the memory cell included in the fourth string ST4, among the memory cells coupled to the word line WL2 (program sequence 20). As described above, the second program operation may be performed by sequentially selecting memory cells corresponding to the second page from among the plurality of strings included in the selected memory block and by programming MSB data to the selected memory cells.

Thereafter, the peripheral circuits 200 may perform the first program operation on a fourth page composed of memory cells coupled to a word line WL4, from the selected memory block, under the control of the control logic 300, and may be controlled such that the memory cells are sequentially selected and programmed, at step S670.

Referring to FIG. 7, after LSB data is programmed to a memory cell included in the first string ST1, among memory cells coupled to the word line WL4 (program sequence 21), the LSB data is programmed to a memory cell included in the second string ST2, among the memory cells coupled to the word line WL4 (program sequence 22). Thereafter, after LSB data is programmed to a memory cell included in the third string ST3, among the memory cells coupled to the word line WL4 (program sequence 23), the LSB data is programmed to a memory cell included in the fourth string ST4, among the memory cells coupled to the word line WL4 (program sequence 24). As described above, the first program operation may be performed by sequentially selecting memory cells corresponding to the fourth page, among the plurality of strings included in the selected memory block, and by programming LSB data to the selected memory cells.

Thereafter, the peripheral circuits 200 may perform a second program operation on the third page of the selected memory block under the control of the control logic 300, and may be controlled such that memory cells are sequentially selected and programmed, at step S680.

Referring to FIG. 7, after MSB data is programmed to the memory cell included in the first string ST1, among the memory cells coupled to the word line WL3 (program sequence 25), the MSB data is programmed to the memory cell included in the second string ST2, among the memory cells coupled to the word line WL3 (program sequence 26). Thereafter, after MSB data is programmed to the memory cell included in the third string ST3, among the memory cells coupled to the word line WL3 (program sequence 27), the MSB data is programmed to the memory cell included in the fourth string ST4, among the memory cells coupled to the word line WL3 (program sequence 28). As described above, the second program operation may be performed by sequentially selecting memory cells corresponding to the third page from among the plurality of strings included in the selected memory block and by programming MSB data to the selected memory cells.

In the above-described program sequence, the first program operation and the second program operation are performed on each page. Finally, the second program operation on an n-th page composed of memory cells coupled to a word line WLn is performed and is controlled such that the memory cells are sequentially selected and programmed, at step S690.

In accordance with the program operation method, after the first program operation is sequentially performed on a selected page (e.g., first page) (see program sequences 1 to 4), the first program operation is sequentially performed on a subsequent page (e.g., second page) (see program sequences 5 to 8) before the second program operation is performed on the selected page (see program sequences 9 to 12).

Referring to FIG. 8, in memory cells in the selected page, electrons \textcircled{e} are trapped in a memory layer ML during the first program operation (see program sequences 1 to 4), and a predetermined period of time elapses before the second program operation (see program sequences 9 to 12) is performed, and thus a rearrangement phenomenon occurs in which the trapped electrons \textcircled{e} are discharged to channels or are moved to an adjacent memory layer ML. Due to the rearrangement phenomenon, before the second program operation is performed after the first program operation is performed, the threshold voltages of memory cells of the selected page may decrease. However, the threshold voltages of memory cells of the selected page may increase again to a normal threshold voltage distribution due to the second program operation on the selected page. Further, since the electrons \textcircled{e} are arranged in the adjacent memory layer ML due to the rearrangement phenomenon after the first program operation, the rearrangement phenomenon is suppressed after the second program operation. Therefore, a phenomenon in which the threshold voltage distributions of the memory cells decrease may be suppressed.

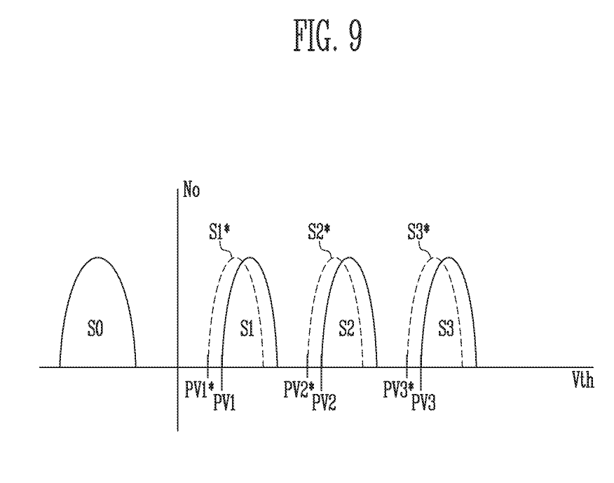

FIG. 9 is a threshold voltage distribution diagram explaining a program operation of a memory system according to an embodiment of the present disclosure.

The program operation of the memory system according to the embodiment of the present disclosure will be described below with reference to FIGS. 1 to 9.

In an embodiment of the present disclosure, an operation of programming memory cells using a re-program scheme will be described by way of example.

When a write request and data are inputted from the host 2000 at step S610 (see FIG. 6), the memory controller 1200 generates a command CMD for controlling the write operation of the memory device 1100 in response to the write request, translates an address received together with the write request into the address of the memory device 1100, and then generates a translated address ADD.

The program sequence controller 1210 of the memory controller 1200 sets a program sequence for a plurality of strings included in a memory block, which is selected from among a plurality of memory blocks included in the memory device 1100 and on which a program operation is to be performed, in response to the write request. For example, the program sequence controller 1210 may set the program sequence so that the plurality of strings included in the selected memory block are sequentially selected and programmed.

The memory controller 1200 transmits the command CMD, the data, and the address ADD to the memory device 1100.

The control logic 300 of the memory device 1100 outputs an operation signal OP_CMD, a row address RADD, and page buffer control signals PBSIGNALS in response to the command CMD and the address ADD, and then controls the peripheral circuits 200 so that the peripheral circuits 200 perform a first program operation on a first page composed of memory cells coupled to a word line WL1, from the selected memory block (e.g., MB1), wherein the memory cells are sequentially selected and programmed, at step S620 (see FIG. 6). Referring to FIG. 7, after a memory cell included in a first string ST1, among memory cells coupled to a word line WL1, is programmed (program sequence 1), a memory cell included in a second string ST2, among the memory cells coupled to the word line WL1, is programmed (program sequence 2). Thereafter, after a memory cell included in a third string ST3, among the memory cells coupled to the word line WL1, is programmed (program sequence 3), a memory cell included in a fourth string ST4, among the memory cells coupled to the word line WL1, is programmed (program sequence 4). As described above, the first program operation may be performed by sequentially selecting memory cells corresponding to the first page, among the plurality of strings included in the selected memory block.

Referring to FIG. 9, the first program operation may maintain the threshold voltage of a memory cell that is in an erase state S0 without change, or may program the memory cell to a state higher than those of target levels PV1*, PV2*, and PV3*. In the embodiment shown in FIG. 9, the target levels PV1*, PV2*, and PV3* of the first program operation may be lower than the target levels PV1, PV2, and PV3 of the second program operation. However, depending on an embodiment, the target levels PV1*, PV2*, and PV3* of the first program operation may be set to the same levels as the target levels PV1, PV2, and PV3 of the second program operation. As a result of the first program operation, memory cells corresponding to the first page, among the memory cells included in the first to fourth strings ST1 to ST4, may be programmed to have a program state corresponding to any one of S0, S1*, S2*, and S3*.

Thereafter, the peripheral circuits 200 may perform the first program operation on a second page composed of memory cells coupled to a word line WL2, from the selected memory block, under the control of the control logic 300, and may be controlled such that the memory cells are sequentially selected and programmed, at step S630 (see FIG. 6). Referring to FIG. 7, after a memory cell included in the first string ST1, among memory cells coupled to a word line WL2, is programmed (program sequence 5), a memory cell included in the second string ST2, among the memory cells coupled to the word line WL2, is programmed (program sequence 6). After a memory cell included in the third string ST3, among the memory cells coupled to the word line WL2, is programmed (program sequence 7), a memory cell included in the fourth string ST4, among the memory cells coupled to the word line WL2, is programmed (program sequence 8). As described above, the first program operation may be performed by sequentially selecting memory cells corresponding to the second page, among the plurality of strings included in the selected memory block.

Thereafter, the peripheral circuits 200 may perform the second program operation on the first page of the selected memory block under the control of the control logic 300, and may be controlled such that memory cells are sequentially selected and programmed, at step S640 (see FIG. 6). Referring to FIG. 7, after the memory cell included in the first string ST1, among memory cells coupled to the word line WL1, is programmed (program sequence 9), the memory cell included in the second string ST2, among the memory cells coupled to the word line WL1, is programmed (program sequence 10). Thereafter, after the memory cell included in the third string ST3, among the memory cells coupled to the word line WL1, is programmed (program sequence 11), the memory cell included in the fourth string ST4, among the memory cells coupled to the word line WL1, is programmed (program sequence 12). As described above, the second program operation may be performed by sequentially selecting memory cells corresponding to the first page, among the plurality of strings included in the selected memory block.

Referring to FIG. 9, the second program operation may maintain the threshold voltage of a memory cell after the first program operation in an erase state S0 without change, or may program the memory cell to a state higher than those of target levels PV1, PV2, and PV3. As a result of the second program operation, memory cells corresponding to the first page, among the memory cells included in the first to fourth strings ST1 to ST4, may be programmed to have a program state corresponding to any one of S0, S1, S2, and S3.

Thereafter, the peripheral circuits 200 may performthe first program operation on a third page composed of memory cells coupled to a word line WL3, from the selected memory block under the control of the control logic 300, and may be controlled such that the memory cells are sequentially selected and programmed, at step S650 (see FIG. 6). Referring to FIG. 7, after a memory cell included in the first string ST1, among memory cells coupled to the word line WL3, is programmed (program sequence 13), a memory cell included in the second string ST2, among the memory cells coupled to the word line WL3, is programmed (program sequence 14). Thereafter, after a memory cell included in the third string ST3, among the memory cells coupled to the word line WL3, programmed (program sequence 15), a memory cell included in the fourth string ST4, among the memory cells coupled to the word line WL3, is programmed (program sequence 16). As described above, the first program operation may be performed by sequentially selecting memory cells corresponding to the third page, among the plurality of strings included in the selected memory block.

Thereafter, the peripheral circuits 200 may perform a second program operation on the second page of the selected memory block under the control of the control logic 300, and may be controlled such that memory cells are sequentially selected and programmed, at step S660 (see FIG. 6). Referring to FIG. 7, after the memory cell included in the first string ST1, among memory cells coupled to a word line WL2, is programmed (program sequence 17), the memory cell included in the second string ST2, among the memory cells coupled to the word line WL2, is programmed (program sequence 18). After the memory cell included in the third string ST3, among the memory cells coupled to the word line WL2, is programmed (program sequence 19), the memory cell included in the fourth string ST4, among the memory cells coupled to the word line WL2, is programmed (program sequence 20). As described above, the second program operation may be performed by sequentially selecting memory cells corresponding to the second page, among the plurality of strings included in the selected memory block.

Thereafter, the peripheral circuits 200 may perform the first program operation on a fourth page composed of memory cells coupled to a word line WL4, from the selected memory block, under the control of the control logic 300, and may be controlled such that the memory cells are sequentially selected and programmed, at step S670 (see FIG. 6). Referring to FIG. 7, after a memory cell included in the first string ST1, among memory cells coupled to the word line WL4, is programmed (program sequence 21), a memory cell included in a second string ST2, among the memory cells coupled to the word line WL4, is programmed (program sequence 22). Thereafter, after a memory cell included in the third string ST3, among the memory cells coupled to the word line WL4, is programmed (program sequence 23), a memory cell included in the fourth string ST4, among the memory cells coupled to the word line WL4, is programmed (program sequence 24). As described above, the first program operation may be performed by sequentially selecting memory cells corresponding to the fourth page, among the plurality of strings included in the selected memory block.

Thereafter, the peripheral circuits 200 may perform a second program operation on the third page of the selected memory block under the control of the control logic 300, and may be controlled such that memory cells are sequentially selected and programmed, at step S680 (see FIG. 6). Referring to FIG. 7, after the memory cell included in the first string ST1, among the memory cells coupled to the word line WL3, programmed (program sequence 25), the memory cell included in the second string ST2, among the memory cells coupled to the word line WL3, is programmed (program sequence 26). Thereafter, after the memory cell included in the third string ST3, among the memory cells coupled to the word line WL3, is programmed (program sequence 27), the memory cell included in the fourth string ST4, among the memory cells coupled to the word line WL3, is programmed (program sequence 28). As described above, the second program operation may be performed by sequentially selecting memory cells corresponding to the third page, among the plurality of strings included in the selected memory block.

In the above-described program sequence, the first program operation and the second program operation are performed on each page. Finally, the second program operation on an n-th page composed of memory cells coupled to a word line WLn is performed and is controlled such that the memory cells are sequentially selected and programmed, at step S690 (see FIG. 6).

In an embodiment of the present disclosure, although the re-program operation is described as including the first and second program operations, it may include first to y-th (where y is an integer greater than or equal to 2) program operations, and target levels of respective program operations may be identical to each other, or alternatively, the target level of the first program operation may be lower than those of other program operations.

In accordance with the program operation method, after the first program operation is sequentially performed on a selected page (e.g., first page) (see program sequences 1 to 4), the first program operation is sequentially performed on a subsequent page (e.g., second page) (see program sequences 5 to 8) before the second program operation is performed on the selected page (see program sequences 9 to 12). Referring to FIG. 8, in memory cells in the selected page, electrons \textcircled{e} are trapped in a memory layer ML during the first program operation (see program sequences 1 to 4), and a predetermined period of time elapses before the second program operation (see program sequences 9 to 12) is performed, and thus a rearrangement phenomenon occurs in which the trapped electrons \textcircled{e} are discharged to channels or are moved to an adjacent memory layer ML. Due to the rearrangement phenomenon, before the second program operation is performed after the first program operation is performed, the threshold voltages of memory cells of the selected page may decrease. However, the threshold voltages of memory cells of the selected page may increase again to a normal threshold voltage distribution due to the second program operation on the selected page. Further, since the electrons are arranged in the adjacent memory layer ML due to the rearrangement phenomenon after the first program operation, the rearrangement phenomenon is suppressed after the second program operation. Therefore, a phenomenon in which the threshold voltage distributions of the memory cells decrease may be suppressed.

FIG. 10 is a flowchart illustrating a program operation of a memory system according to an embodiment of the present disclosure.

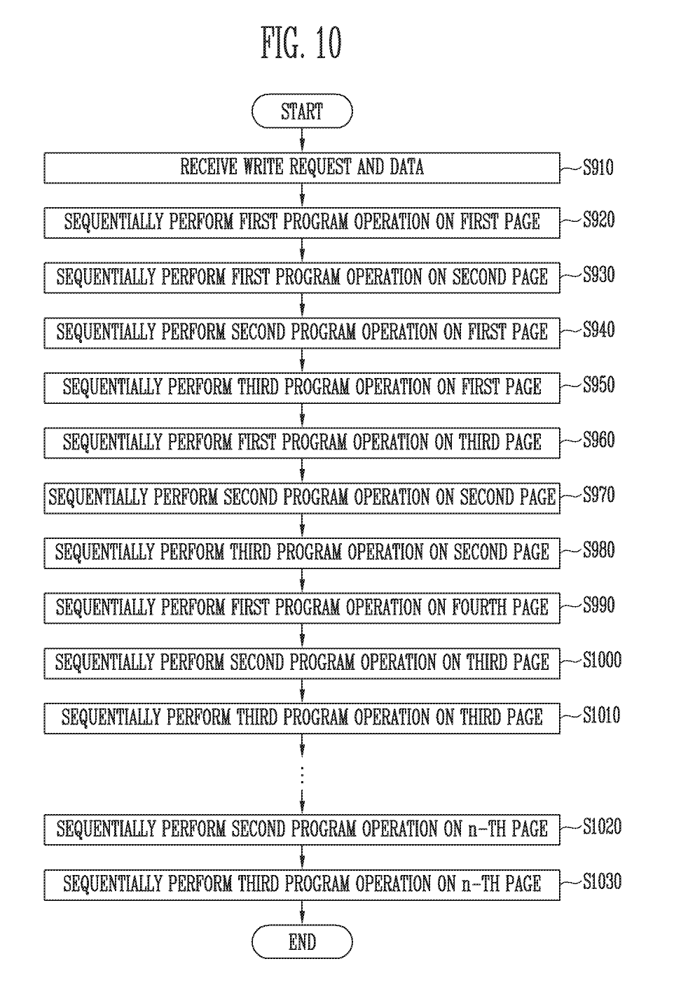

FIG. 11 is a diagram illustrating the sequence of program operations according to an embodiment of the present disclosure. FIG. 11 shows memory cells with numbers representing a program sequence.

The program operation of the memory system according to an embodiment of the present disclosure will be described below with reference to FIGS. 1, 5, 8, 10, and 11.

In an embodiment of the present disclosure, a program operation performed in a TLC scheme will be described by way of example. However, it is to be noted that the present invention is not limited to the TLC scheme.

When a write request and data are inputted from the host 2000 at step S910, the memory controller 1200 generates a command CMD for controlling the write operation of the memory device 1100 in response to the write request, translates an address received together with the write request into the address of the memory device 1100, and then generates a translated address ADD.

The program sequence controller 1210 of the memory controller 1200 sets a program sequence for a plurality of strings included in a memory block, which is selected from among a plurality of memory blocks included in the memory device 1100 and on which a program operation is to be performed, in response to the write request. For example, the program sequence controller 1210 may set the program sequence so that the plurality of strings included in the selected memory block are sequentially selected and programmed.

The memory controller 1200 transmits the command CMD, the data, and the address ADD to the memory device 1100.

The control logic 300 of the memory device 1100 outputs an operation signal OP_CMD, a row address RADD, and page buffer control signals PBSIGNALS in response to the command CMD and the address ADD, and then controls the peripheral circuits 200 so that the peripheral circuits 200 perform a first program operation on a first page composed of memory cells coupled to a word line WL1, from the selected memory block (e.g., MB1), wherein the memory cells are sequentially selected and programmed, at step S920.

Referring to FIG. 11, after LSB data is programmed to a memory cell included in a first string ST1, among memory cells coupled to the word line WL1 (program sequence 1), the LSB data is programmed to a memory cell included in a second string ST2, among the memory cells coupled to the word line WL1 (program sequence 2). After LSB data is programmed to a memory cell included in a third string ST3, among the memory cells coupled to the word line WL1 (program sequence 3), the LSB data is programmed to a memory cell included in a fourth string ST4, among the memory cells coupled to the word line WL1 (program sequence 4). As described above, the first program operation may be performed by sequentially selecting memory cells corresponding to the first page from among the plurality of strings included in the selected memory block and by programming LSB data to the selected memory cells.

Thereafter, the peripheral circuits 200 may perform the first program operation on a second page composed of memory cells coupled to a word line WL2, from the selected memory block, under the control of the control logic 300, and may be controlled such that the memory cells are sequentially selected and programmed, at step S930. Referring to FIG. 11, after LSB data is programmed to a memory cell included in the first string ST1, among the memory cells coupled to the word line WL2 (program sequence 5), the LSB data is programmed to a memory cell included in the second string ST2, among the memory cells coupled to the word line WL2 (program sequence 6). After LSB data is programmed to a memory cell included in the third string ST3, among the memory cells coupled to the word line WL2 (program sequence 7), the LSB data is programmed to a memory cell included in the fourth string ST4, among the memory cells coupled to the word line WL2 (program sequence 8). As described above, the first program operation may be performed by sequentially selecting memory cells corresponding to the second page, among the plurality of strings included in the selected memory block, and by programming LSB data to the selected memory cells.

Thereafter, the peripheral circuits 200 may perform a second program operation on the first page of the selected memory block under the control of the control logic 300, and may be controlled such that memory cells are sequentially selected and programmed, at step S940.

Referring to FIG. 11, after CSB data is programmed to the memory cell included in the first string ST1, among memory cells coupled to the word line WL1 (program sequence 9), the CSB data is programmed to the memory cell included in the second string ST2, among the memory cells coupled to the word line WL1 (program sequence 10). Thereafter, after CSB data is programmed to the memory cell included in the third string ST3, among the memory cells coupled to the word line WL1 (program sequence 11), the CSB data is programmed to the memory cell included in the fourth string ST4, among the memory cells coupled to the word line WL1 (program sequence 12). As described above, the second program operation may be performed by sequentially selecting memory cells corresponding to the first page from among the plurality of strings included in the selected memory block and by programming CSB data to the selected memory cells.

Thereafter, the peripheral circuits 200 may perform a third program operation on the first page of the selected memory block under the control of the control logic 300, and may be controlled such that memory cells are sequentially selected and programmed, at step S950.

Referring to FIG. 11, after MSB data is programmed to a memory cell included in the first string ST1, among memory cells coupled to the word line WL1 (program sequence 13), the MSB data is programmed to a memory cell included in the second string ST2, among the memory cells coupled to the word line WL1 (program sequence 14). Thereafter, after MSB data is programmed to a memory cell included in the third string ST3, among the memory cells coupled to the word line WL1 (program sequence 15), the MSB data is programmed to a memory cell included in the fourth string ST4, among the memory cells coupled to the word line WL1 (program sequence 16). As described above, the third program operation may be performed by sequentially selecting memory cells corresponding to the first page from among the plurality of strings included in the selected memory block and by programming MSB data to the selected memory cells.

Thereafter, the peripheral circuits 200 may perform the first program operation on a third page composed of memory cells coupled to a word line WL3, from the selected memory block, under the control of the control logic 300, and may be controlled such that the memory cells are sequentially selected and programmed, at step S960.

Referring to FIG. 11, after LSB data is programmed to a memory cell included in the first string ST1, among the memory cells coupled to the word line WL3 (program sequence 17), the LSB data is programmed to a memory cell included in the second string ST2, among the memory cells coupled to the word line WL3 (program sequence 18). Thereafter, after LSB data is programmed to a memory cell included in the third string ST3, among the memory cells coupled to the word line WL3 (program sequence 19), the LSB data is programmed to a memory cell included in the fourth string ST4, among the memory cells coupled to the word line WL3 (program sequence 20). As described above, the first program operation may be performed by sequentially selecting memory cells corresponding to the third page, among the plurality of strings included in the selected memory block, and by programming LSB data to the selected memory cells.

Thereafter, the peripheral circuits 200 may perform a second program operation on the second page of the selected memory block under the control of the control logic 300, and may be controlled such that memory cells are sequentially selected and programmed, at step S970.

Referring to FIG. 11, after CSB data is programmed to the memory cell included in the first string ST1, among memory cells coupled to the word line WL2 (program sequence 21), the CSB data is programmed to the memory cell included in the second string ST2, among the memory cells coupled to the word line WL2 (program sequence 22). Thereafter, after CSB data is programmed to the memory cell included in the third string ST3, among the memory cells coupled to the word line WL2 (program sequence 23), the CSB data is programmed to the memory cell included in the fourth string ST4, among the memory cells coupled to the word line WL2 (program sequence 24). As described above, the second program operation may be performed by sequentially selecting memory cells corresponding to the second page from among the plurality of strings included in the selected memory block and by programming CSB data to the selected memory cells.

Thereafter, the peripheral circuits 200 may perform a third program operation on the second page of the selected memory block under the control of the control logic 300, and may be controlled such that memory cells are sequentially selected and programmed, at step S980.

Referring to FIG. 11, after MSB data is programmed to the memory cell included in the first string ST1, among the memory cells coupled to the word line WL2 (program sequence 25), the MSB data is programmed to the memory cell included in the second string ST2, among the memory cells coupled to the word line WL2 (program sequence 26). Thereafter, after MSB data is programmed to the memory cell included in the third string ST3, among the memory cells coupled to the word line WL2 (program sequence 27), the MSB data is programmed to the memory cell included in the fourth string ST4, among the memory cells coupled to the word line WL2 (program sequence 28). As described above, the third program operation may be performed by sequentially selecting memory cells corresponding to the second page from among the plurality of strings included in the selected memory block and by programming MSB data to the selected memory cells.

Thereafter, the peripheral circuits 200 may perform the first program operation on a fourth page composed of memory cells coupled to a word line WL4, from the selected memory block, under the control of the control logic 300, and may be controlled such that the memory cells are sequentially selected and programmed, at step S990.

Referring to FIG. 11, after LSB data is programmed to a memory cell included in the first string ST1, among memory cells coupled to the word line WL4 (program sequence 29), the LSB data is programmed to a memory cell included in the second string ST2, among the memory cells coupled to the word line WL4 (program sequence 30). Thereafter, after LSB data is programmed to a memory cell included in the third string ST3, among the memory cells coupled to the word line WL4 (program sequence 31), the LSB data is programmed to a memory cell included in the fourth string ST4, among the memory cells coupled to the word line WL4 (program sequence 32). As described above, the first program operation may be performed by sequentially selecting memory cells corresponding to the fourth page, among the plurality of strings included in the selected memory block, and by programming LSB data to the selected memory cells.

Thereafter, the peripheral circuits 200 may perform a second program operation on the third page of the selected memory block under the control of the control logic 300, and may be controlled such that memory cells are sequentially selected and programmed, at step S1000.

Referring to FIG. 11, after CSB data is programmed to the memory cell included in the first string ST1, among memory cells coupled to the word line WL3 (program sequence 33), the CSB data is programmed to the memory cell included in the second string ST2, among the memory cells coupled to the word line WL3 (program sequence 34). Thereafter, after CSB data is programmed to the memory cell included in the third string ST3, among the memory cells coupled to the word line WL3 (program sequence 35), the CSB data is programmed to the memory cell included in the fourth string ST4, among the memory cells coupled to the word line WL3 (program sequence 36). As described above, the second program operation may be performed by sequentially selecting memory cells corresponding to the third page from among the plurality of strings included in the selected memory block and by programming CSB data to the selected memory cells.

Thereafter, the peripheral circuits 200 may perform a third program operation on the third page of the selected memory block under the control of the control logic 300, and may be controlled such that memory cells are sequentially selected and programmed, at step S1010.

Referring to FIG. 11, after MSB data is programmed to the memory cell included in the first string ST1, among the memory cells coupled to the word line WL3 (program sequence 37), the MSB data is programmed to the memory cell included in the second string ST2, among the memory cells coupled to the word line WL3 (program sequence 38). After MSB data is programmed to the memory cell included in the third string ST3, among the memory cells coupled to the word line WL3 (program sequence 39), the MSB data is programmed to the memory cell included in the fourth string ST4, among the memory cells coupled to the word line WL3 (program sequence 40). As described above, the third program operation may be performed by sequentially selecting memory cells corresponding to the third page from among the plurality of strings included in the selected memory block and by programming MSB data to the selected memory cells.

In the above-described program sequence, the first to third program operations are performed on each page. Finally, the second program operation and the third program operation are successively performed on an n-th page composed of memory cells coupled to a word line WLn respectively at steps S1020 and S1030. In this case, the second program operation is performed at step S1020 such that memory cells corresponding to the n-th page are sequentially selected and CSB data is programmed to the selected memory cells, and the third program operation is performed at step S1030 such that memory cells corresponding to the n-th page are sequentially selected and MSB data is programmed to the selected memory cells.

In accordance with the program operation method, after the first program operation is sequentially performed on a selected page (e.g., first page) (see program sequences 1 to 4), the first program operation is sequentially performed on a subsequent page (e.g., second page) (see program sequences 5 to 8) before the second program operation is performed on the selected page (see program sequences 9 to 12).

Referring to FIG. 8, in memory cells in the selected page, electrons \textcircled{e} are trapped in a memory layer ML during the first program operation (see program sequences 1 to 4), and a predetermined period of time elapses before the second program operation (see program sequences 9 to 12) is performed, and thus a rearrangement phenomenon occurs in which the trapped electrons \textcircled{e} are discharged to channels or are moved to an adjacent memory layer ML. Due to the rearrangement phenomenon, before the second program operation is performed after the first program operation is performed, the threshold voltages of memory cells of the selected page may decrease. However, the threshold voltages of memory cells of the selected page may increase again to a normal threshold voltage distribution due to the second program operation on the selected page. Further, since the electrons \textcircled{e} are arranged in the adjacent memory layer ML due to the rearrangement phenomenon after the first program operation, the rearrangement phenomenon is suppressed after the second program operation. Therefore, a phenomenon in which the threshold voltage distributions of the memory cells decrease may be suppressed.

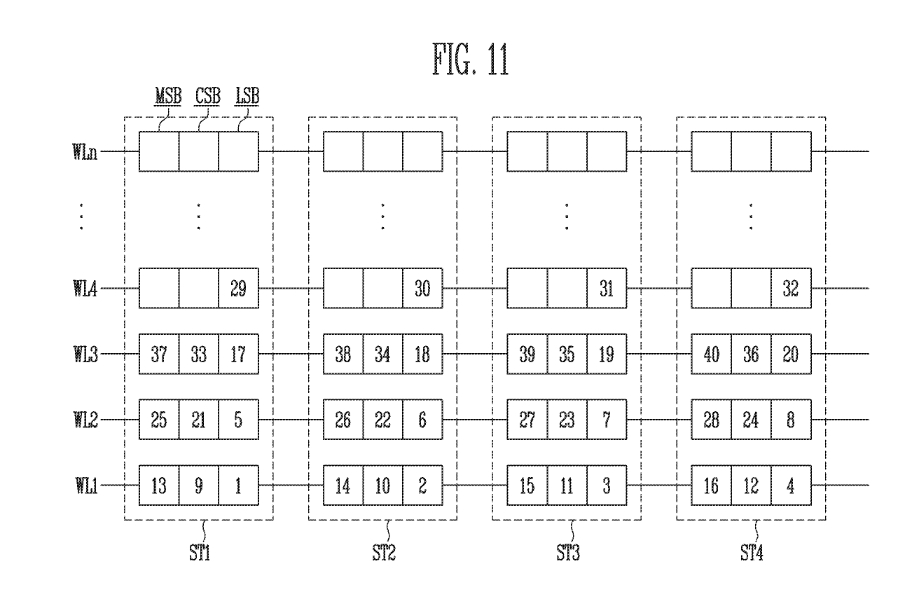

FIG. 12 is a diagram illustrating an embodiment of a memory system including the memory device of FIG. 2.

Referring to FIG. 12, a memory system 30000 may be embodied in a cellular phone, a smartphone, a tablet PC, a personal digital assistant (PDA) or a wireless communication device. The memory system 30000 may include the memory device 1100 and a memory controller 1200 capable of controlling the operation of the memory device 1100. The memory controller 1200 may control a data access operation, e.g., a program, erase, or read operation, of the memory device 1100 under the control of a processor 3100.

Data programmed in the memory device 1100 may be output through a display 3200 under the control of the memory controller 1200.

A radio transceiver 3300 may send and receive radio signals through an antenna ANT. For example, the radio transceiver 3300 may change a radio signal received through the antenna ANT into a signal which may be processed by the processor 3100. Therefore, the processor 3100 may process a signal output from the radio transceiver 3300 and transmit the processed signal to the memory controller 1200 or the display 3200. The memory controller 1200 may program a signal processed by the processor 3100 to the memory device 1100. Furthermore, the radio transceiver 3300 may change a signal output from the processor 3100 into a radio signal, and output the changed radio signal to the external device through the antenna ANT. An input device 3400 may be used to input a control signal for controlling the operation of the processor 3100 or data to be processed by the processor 3100. The input device 3400 may be implemented as a pointing device such as a touch pad or a computer mouse, a keypad or a keyboard. The processor 3100 may control the operation of the display 3200 such that data output from the memory controller 1200, data output from the radio transceiver 3300, or data output from the input device 3400 is output through the display 3200.

In an embodiment, the memory controller 1200 capable of controlling the operation of the memory device 1100 may be implemented as a part of the processor 3100 or a chip provided separately from the processor 3100.

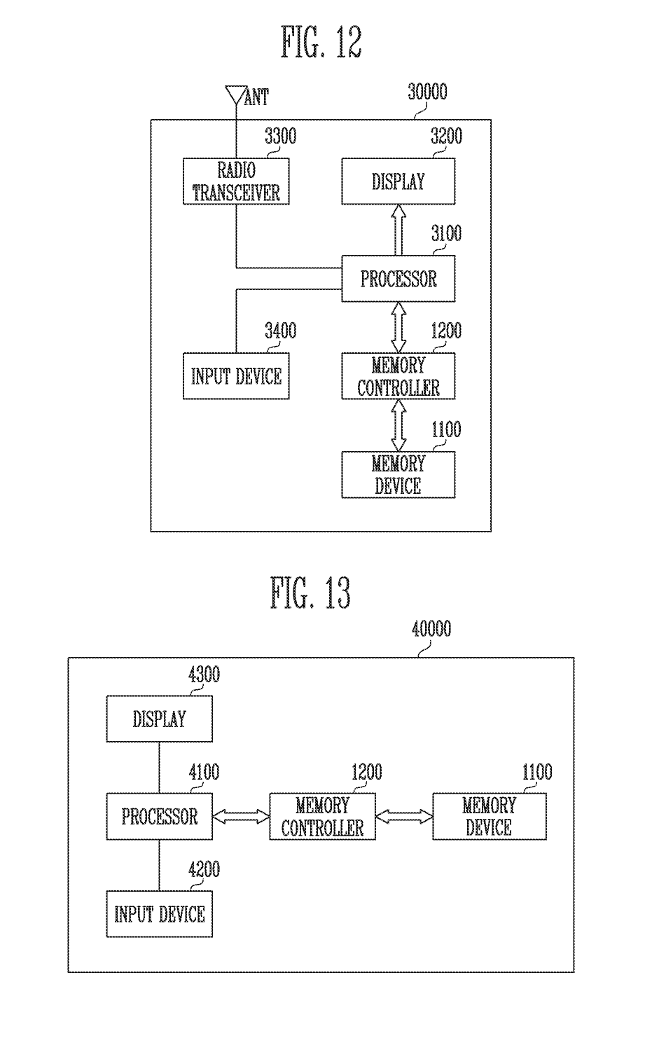

FIG. 13 is a diagram illustrating an embodiment of a memory system including the memory device of FIG. 2.

Referring to FIG. 13, a memory system 40000 may be embodied in a personal computer, a tablet PC, a net-book, an e-reader, a personal digital assistant (PDA), a portable multimedia player (PMP), an MP3 player, or an MP4 player.

The memory system 40000 may include the memory device 1100 and a memory controller 1200 capable of controlling the data processing operation of the memory device 1100.

A processor 4100 may output data stored in the memory device 1100 through a display 4300, according to data input from an input device 4200. For example, the input device 4200 may be implemented as a point device such as a touch pad or a computer mouse, a keypad or a keyboard.

The processor 4100 may control the overall operation of the memory system 40000 and control the operation of the memory controller 1200. In an embodiment, the memory controller 1200 capable of controlling the operation of the memory device 1100 may be implemented as a part of the processor 4100 or a chip provided separately from the processor 4100.

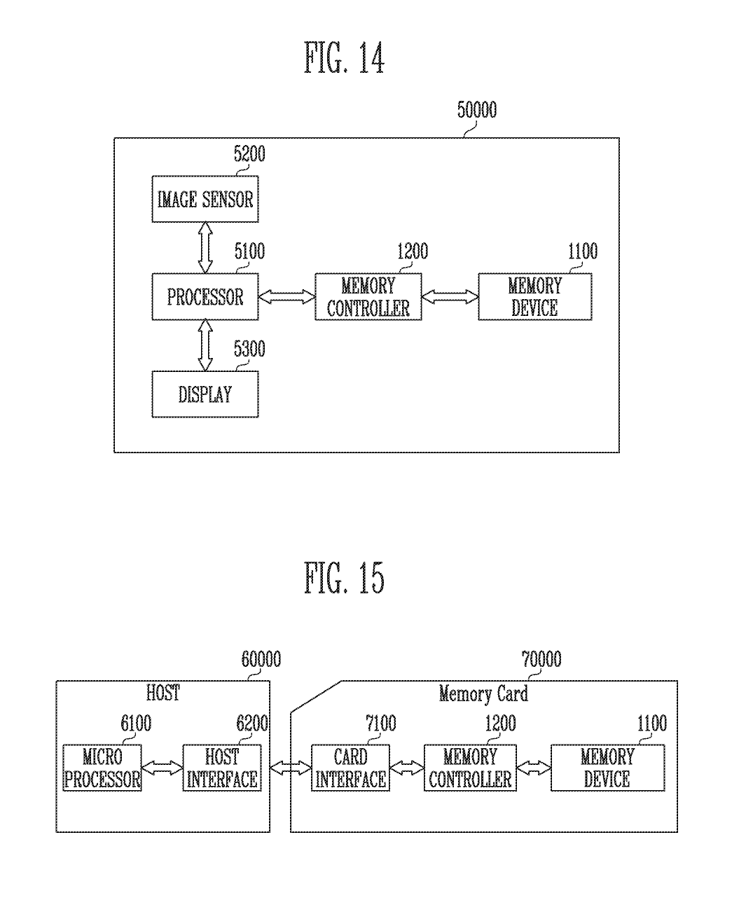

FIG. 14 is a diagram illustrating an embodiment of a memory system including the memory device of FIG. 2.

Referring to FIG. 14, a memory system 50000 may be embodied in an image processing device, e.g., a digital camera, a portable phone provided with a digital camera, a smartphone provided with a digital camera, or a tablet PC provided with a digital camera.

The memory system 50000 may include the memory device 1100 and a memory controller 1200 capable of controlling a data processing operation, e.g., a program, erase, or read operation, of the memory device 1100.

An image sensor 5200 of the memory system 50000 may convert an optical image into digital signals. The converted digital signals may be transmitted to a processor 5100 or the memory controller 1200. Under the control of the processor 5100, the converted digital signals may be output through a display 5300 or stored in the memory device 1100 through the memory controller 1200. Data stored in the memory device 1100 may be output through the display 5300 under the control of the processor 5100 or the memory controller 1200.

In an embodiment, the memory controller 1200 capable of controlling the operation of the memory device 1100 may be implemented as a part of the processor 5100, or a chip provided separately from the processor 5100.

FIG. 15 is a diagram illustrating an embodiment of a memory system including the memory device of FIG. 2.

Referring to FIG. 15, a memory system 70000 may be embodied in a memory card or a smart card. The memory system 70000 may include the memory device 1100, a memory controller 1200 and a card interface 7100.

The memory controller 1200 may control data exchange between the memory device 1100 and the card interface 7100. In an embodiment, the card interface 7100 may be a secure digital (SD) card interface or a multi-media card (MMC) interface, but it is not limited thereto.

The card interface 7100 may interface data exchange between a host 60000 and the memory controller 1200 according to a protocol of the host 60000. In an embodiment, the card interface 7100 may support a universal serial bus (USB) protocol, and an inter-chip (IC)-USB protocol. Here, the card interface may refer to hardware capable of supporting a protocol which is used by the host 60000, software installed in the hardware, or a signal transmission method.

When the memory system 70000 is connected to a host interface 6200 of the host 60000 such as a PC, a tablet PC, a digital camera, a digital audio player, a cellular phone, console video game hardware or a digital set-top box, the host interface 6200 may perform data communication with the memory device 1100 through the card interface 7100 and the memory controller 1200 under the control of a microprocessor 6100.

In accordance with the present disclosure, a predetermined period of time is allocated for each memory cell before a second program operation is performed after a first program operation is performed, so that electrons trapped by the first program operation are redistributed for the predetermined period of time, after which the second program operation is performed, thus improving threshold voltage distributions of memory cells.

Examples of embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A memory system, comprising:
a memory device comprising a memory block composed of a plurality of strings; and
a memory controller configured to control the memory device to perform a program operation on the memory block in response to a write request received from a host,
wherein the memory device programs the plurality of strings by sequentially selecting the strings during the program operation.

2. The memory system according to claim 1, wherein the memory device further comprises:
peripheral circuits configured to perform the program operation on the memory block; and
a control logic configured to control the peripheral circuits in response to a command and an address outputted from the memory controller.

3. The memory system according to claim 2, wherein the peripheral circuits comprise:
a voltage generation circuit configured to generate operating voltages in response to an operation signal outputted from the control logic;
a row decoder configured to transfer the operating voltages to word lines of the memory block in response to a row address; and
a page buffer group including a plurality of page buffers,
wherein the page buffer group controls potential levels of bit lines of the memory block based on data to be programmed in the program operation in response to page buffer control signals outputted from the control logic.

4. The memory system according to claim 3, wherein the plurality of page buffers are sequentially activated during the program operation, and an activated page buffer, among the plurality of page buffers, controls a potential level of a corresponding bit line, among the bit lines, based on the data to be programmed.

5. The memory system according to claim 4, wherein remaining page buffers, which are deactivated, among the plurality of page buffers, apply a program prohibition voltage to the corresponding bit lines.

6. The memory system according to claim 1, wherein the memory block comprises a plurality of pages.

7. The memory system according to claim 6, wherein the memory device performs a first program operation of programming Least Significant Bit (LSB) data and a second program operation of programming Most Significant Bit (MSB) data during the program operation.

8. The memory system according to claim 7, wherein the memory device is configured to:
perform the first program operation such that, after the first program operation is performed by sequentially selecting memory cells included in a first page of the plurality of pages, the first program operation is performed by sequentially selecting memory cells included in a second page of the plurality of pages, and
perform the second program operation by sequentially selecting the memory cells included in the first page after the first program operation.

9. The memory system according to claim 6, wherein the memory device performs a first program operation of programming Least Significant Bit (LSB) data, a second program operation of programming Central Significant Bit (CSB) data, and a third program operation of programming Most Significant Bit (MSB) data during the program operation.

10. The memory system according to claim 9, wherein the memory device is configured to:
perform the first program operation such that, after the first program operation is performed by sequentially selecting memory cells included in a first page of the plurality of pages, the first program operation is performed by sequentially selecting memory cells included in a second page of the plurality of pages,
perform the second program operation by sequentially selecting the memory cells included in the first page after the first program operation, and
perform the third program operation by sequentially selecting the memory cells included in the first page after the second program operation.

11. The memory system according to claim 10, wherein the memory device is configured to, after the third program operation is performed on the first page,
perform the first program operation by sequentially selecting memory cells included in a third page of the plurality of pages,
perform the second program operation by sequentially selecting the memory cells included in the second page after the first program operation, and
perform the third program operation by sequentially selecting the memory cells included in the second page after the second program operation.

12. A method of operating a memory system, comprising:
performing a first program operation by selecting a first page from among a plurality of pages of a memory block;
performing the first program operation by selecting a second page from among the plurality of pages;
performing a second program operation by selecting the first page;
performing the first program operation by selecting a third page from among the plurality of pages; and
performing the second program operation by selecting the second page,
wherein the first program operation is configured to sequentially select and program memory cells included in the selected page.

13. The method according to claim 12, wherein the second program operation is configured to sequentially select and program memory cells included in the selected page.

14. The method according to claim 12, wherein the first program operation is an operation of programming Least Significant Bit (LSB) data, and the second program operation is an operation of programming Most Significant Bit (MSB) data.

15. The method according to claim 12, wherein each of the plurality of pages performs the second program operation after a predetermined period of time has elapsed from performance of the first program operation.

16. A method of operating a memory system, comprising:
performing a first program operation by selecting a first page from among a plurality of pages of a memory block;
performing the first program operation by selecting a second page from among the plurality of pages;
successively performing a second program operation and a third program operation by selecting the first page;
performing the first program operation by selecting a third page from among the plurality of pages;
successively performing the second program operation and the third program operation by selecting the second page; and
performing the first program operation by selecting a fourth page from among the plurality of pages,
wherein the first program operation is configured to sequentially select and program memory cells included in the selected page.

17. The method according to claim 16, further comprising:
after the first program operation is performed on the fourth page, sequentially performing the second program operation and the third program operation by selecting the third page.

18. The method according to claim 16, wherein the first program operation is an operation of programming Least Significant Bit (LSB) data, the second program operation is an operation of programming Central Significant Bit (CSB) data, and the third program operation is an operation of programming Most Significant Bit (MSB) data.

19. The method according to claim 16, wherein the second program operation is configured to sequentially select and program memory cells included in the selected page.

20. The method according to claim 16, wherein the third program operation is configured to sequentially select and program memory cells included in the selected page.
